(19) United States
(12) Patent Application Publication
(10) Pub. No.: US 2024/0206275 A1
(43) Pub. Date: Jun. 20, 2024

(54) DISPLAY DEVICE

(71) Applicant: LG Display Co., Ltd., Seoul (KR)

(72) Inventors: Jonghyun KIM, Paju-si (KR); Seongil KIM, Paju-si (KR)

(21) Appl. No.: 18/470,159

(22) Filed: Sep. 19, 2023

(30) Foreign Application Priority Data
Dec. 16, 2022 (KR) 10-2022-0176531

(51) Int. Cl. H10K 59/38; G02F 1/1335

(52) U.S. Cl. CPC H10K 59/38; G02F 1/133514

(57) ABSTRACT

A display device according to an embodiment includes a first substrate including a display area including a plurality of pixels and a non-display area surrounding the display area, and a color filter arranged on the first substrate, wherein the color filter transmits a specific light incident thereon and blocks other light.

### CROSS-REFERENCE TO RELATED APPLICATION

The present application claims priority to Korean Patent Application No. 10-2022-0176531, filed Dec. 16, 2022, the entire contents of which is incorporated herein for all purposes by this reference.

### BACKGROUND

### Technical Field

The present disclosure relates to a display device.

### Description of the Related Art

Dimming films, attached to the front of display panels in devices such as mobile phones, laptops, tablet personal computers (PCs), car navigation systems, and touchscreens in cars, block light transmitted from the light source and adjust the optical viewing angle according to the incident angle of the light to provide users with clear image quality for users at the desired viewing angle when the display transmits the screen image.

Dimming films can also be used on windows of vehicles or buildings to partially block external light to prevent glare or to make the inside of space not visible from the outside.

That is, a dimming film can be a light path transforming material that controls the direction of light by blocking light in certain directions and allowing light to pass through in specific directions. Therefore, by controlling the angle of light transmission through dimming films, it is possible to control the user's viewing angle.

### BRIEF SUMMARY

The present disclosure provides a display device including a color filter with a viewing angle control function and a color filter function.

The technical features of the present disclosure are not limited to the aforesaid, and other technical features and advantages not described herein with be clearly understood by those skilled in the art from the descriptions below.

A display device according to an embodiment includes a first substrate including a display area including a plurality of pixels and a non-display area surrounding the display area, and a color filter arranged on the first substrate, wherein the color filter transmits a specific light incident from the front and blocks other light.

A display device according to another embodiment includes a first substrate including a display area including a plurality of pixels and a non-display area surrounding the display area, a thin film transistor layer on the first substrate, a color filter on the thin film transistor layer, a liquid crystal layer on the color filter, and a second substrate on the liquid crystal layer, wherein the color filter transmits a specific light incident thereon and blocks other light.

A display device according to still another embodiment includes a first substrate including a display area including a plurality of pixels and a non-display area surrounding the display area, a thin film transistor layer on the first substrate, a light emitting layer on the thin film transistor layer, a thin film encapsulation layer on the light emitting layer, and a color filter on the thin film encapsulation layer, wherein the color filter transmits a specific light incident thereon and blocks other light.

The detailed descriptions of other embodiments are included in the specifications and drawings.

A display device according to the disclosed embodiments is advantageous in terms of eliminating the need for a separate viewing angle control film by adopting a color filter with a viewing angle control function and a color filter function.

As a result, it is possible to reduce the thickness of the display device and simplify the manufacturing process.

The advantages according to the embodiments are not limited to the aforesaid, and a variety of other advantages are included within the specification.

### BRIEF DESCRIPTION OF THE SEVERAL VIEWS OF THE DRAWINGS

FIG. 1 is a plan view of a display device according to an embodiment;

FIG. 2 is a cross-sectional view taken along line I-I′ of FIG. 1;

FIG. 3A is a perspective view of the color filter of FIG. 2;

FIG. 3B is perspective view of a color filter according to an alternative embodiment;

FIG. 4 is a schematic diagram illustrating the function of a color filter of a display device according to an embodiment;

FIGS. 5 to 12 are cross-sectional views illustrating process steps of a method for manufacturing a display device according to an embodiment;

FIG. 13 is a cross-sectional view of a display device according to another embodiment;

FIG. 14 is a cross-sectional view of a display device according to another embodiment;

FIGS. 15 to 20 are cross-sectional views illustrating process steps of a method for manufacturing a display device according to another embodiment;

FIG. 21 is a cross-sectional view of a display device according to another embodiment.

FIG. 22 is a detailed cross-sectional view of a display device according to another embodiment;

FIG. 23 is a cross-sectional view of a display device according to another embodiment; and

FIG. 24 is a cross-sectional view of a display device according to another embodiment.

### DETAILED DESCRIPTION

Technical elements and features of the present disclosure and methods of accomplishing the same may be understood more readily by reference to the following detailed description of embodiments and the accompanying drawings. The disclosed disclosure may, however, be embodied in many different forms and should not be construed as being limited to the example embodiments set forth herein; rather, these example embodiments are provided so that this disclosure will be thorough and complete and will fully convey the concept of the disclosure to those skilled in the art.

When it is mentioned that one device or layer is located on another device or layer, it may be understood that one device or layer is directly located on the other device or layer or that still other device or layer is interposed between the two devices or layers. Throughout the specification, the same reference numerals refer to the same components. The shapes, sizes, ratios, angles, numbers and the like disclosed in the drawings to describe embodiments of the present disclosure are merely examples, and thus, the present disclosure is not limited thereto.

Although the terms “first”, “second”, and the like are used for describing various components, these components are not confined by these terms. These terms are merely used for distinguishing one component from the other components. Accordingly, a first component mentioned earlier may also be a second component within the technical spirit of the present disclosure.

The various features of the embodiments of the present disclosure can be combined or assembled together, either partially or entirely, in a technically diverse manner, and each embodiment can be independently implemented or in conjunction with related embodiments.

Hereinafter, example embodiments of the present disclosure will be described in detail with reference to accompanying drawings.

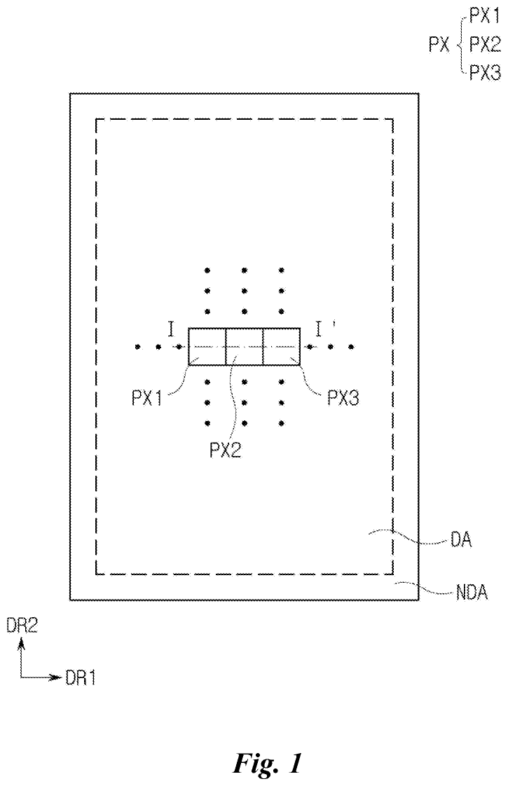

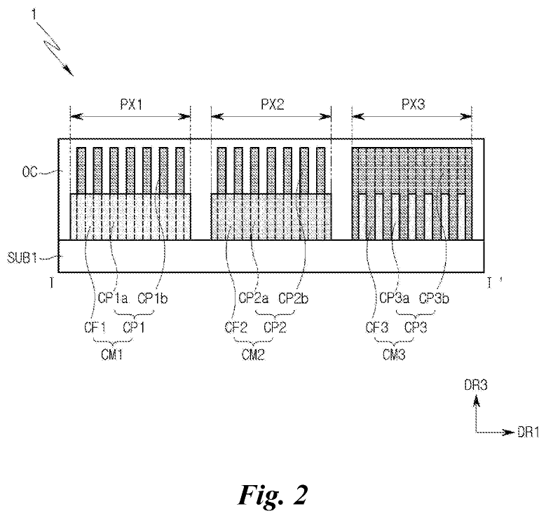

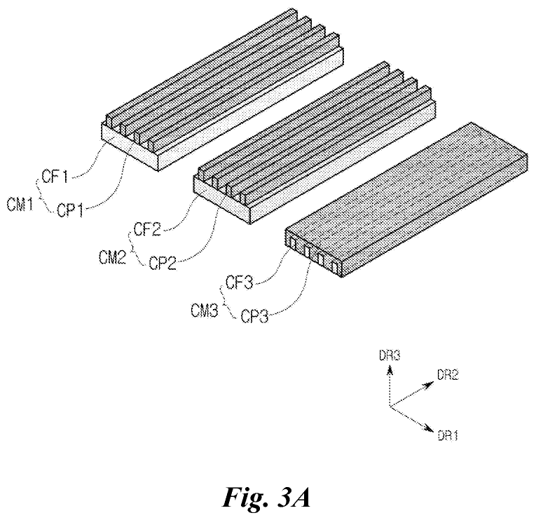

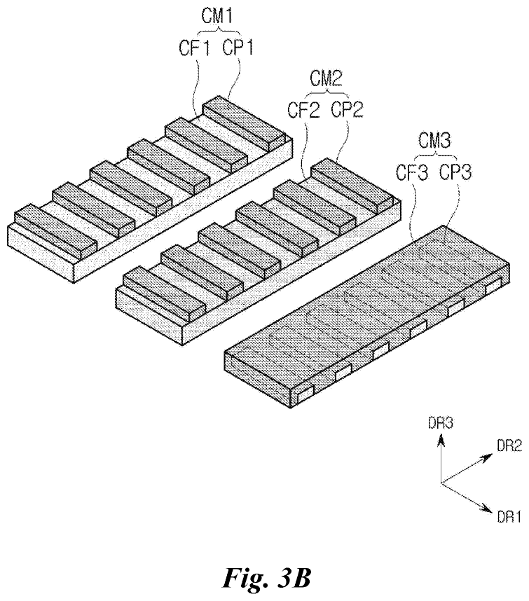

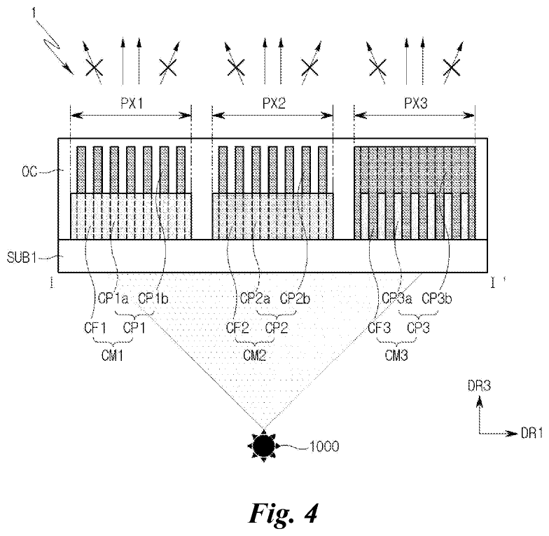

FIG. 1 is a plan view of a display device according to an embodiment; FIG. 2 is a cross-sectional view taken along line I-I′ of FIG. 1. FIG. 3A is a perspective view of the color filter of FIG. 2. FIG. 3B is perspective view of a color filter according to an alternative embodiment. FIG. 4 is a schematic diagram illustrating the function of a color filter of a display device according to an embodiment.

With reference to FIGS. 1 and 4, the display device 1 according to an embodiment may refer to any electronic device that provides a display screen. Examples of the display device 1 may include mobile phones, smartphones, tablet PCs, electronic watches, smartwatches, watch phones, mobile communication terminals, electronic notebooks, electronic books (e-books), Portable Multimedia Players (PMPs), navigation devices, game consoles, digital cameras, televisions, laptops, monitors, advertising displays, and Internet of Things (IOT) devices that are equipped with a display screen.

The display device 1 may include a display panel. The display panel may include a first substrate SUB1, color filters CM1, CM2, and CM3, and a overcoating layer OC. The display panel may include additional components depending on the type of display panel, in addition to the components mentioned above. For convenience of description, various components of the display panel have been omitted in FIGS. 1 to 4.

According to an embodiment of the present disclosure, the display panel may be an organic light emitting diode (OLED) display panel, a liquid crystal display (LCD) panel, a plasma display panel (PDP), an electrophoretic display (EPD) panel, a microelectromechanical system (MEMS) display panel, an electrowetting display (EWD) panel, or the like. In the following description, the display panel of the present disclosure is assumed to be an organic light emitting diode display panel. However, the technical concept of the present disclosure is not limited to this, and various display panels may be applied to the present disclosure according to embodiments.

The display panel 1 may include a display area DA and a non-display area NDA surrounding the display area DA. The display area DA may include a pixel PX. The pixel PX may be provided in plurality. The plurality of pixels PX may be arranged in a matrix array as shown in FIG. 1. The pixels PX may include a first pixel PX1, a second pixel PX2, and a third pixel PX3. The first pixel PX1 may be a region where a first light is emitted (or displayed), the second pixel PX2 may be a region where the second light is emitted, and the third pixel PX3 may be a region where the third light is emitted. The first light may be a red light, the second light may be a green light, and the third light may be a blue light.

Although illustrated as being sequentially arranged in the first direction DR1 in FIG. 1, the pixels PX1 to PX3 are not limited to this configuration and may be arranged in various ways.

As shown in FIG. 2, the display panel may include a first substrate SUB1, color filters CM1, CM2, and CM3 on the first substrate SUB1, and an overcoat layer OC on the color filters CM1, CM2, and CM3.

The first substrate SUB1 may include a glass, plastic, or flexible polymer film. For example, the flexible polymer film may be made of one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, polystyrene (PS), and this is merely an example and not necessarily limited to these materials.

In addition, the first substrate SUB1 may be a flexible substrate with a flexible characteristic.

In addition, the first substrate SUB1 may be a curved or bent substrate. That is, a light path control member including the first substrate SUB1 may be formed to have a flexible, curved, or bent characteristic.

At the same time as controlling the viewing angle of the light emitted from the display device 1, the color filters CM1, CM2, and CM3 may perform a color filter function by transmitting specific colors of light, while blocking other colors of light, for allowing the corresponding pixels PX1, PX2, and PX3 of the display device 1 to emit the first, second, and third light, respectively.

The overcoat layer OC may completely cover the color filters CM1, CM2, and CM3.

The color filters CM1, CM2, and CM3 may include the first color filter CM1 arranged in the first pixel PX1, the second color filter CM2 arranged in the second pixel PX2, and the third color filter CM3 arranged in the third pixel PX3.

The first color filter CM1 may transmit the first light and block the second and third lights, the second color filter CM2 may transmit the second light and block the first and third lights, and the third color filter CM3 may transmit the third light and block the first and second lights. Simultaneously, the color filters CM1, CM2, and CM3 may each play a role in controlling the viewing angle of the light emitted from the display device 1.

The first color filter CM1 may include a first color filter portion CF1 and a first viewing angle control portion CP1 surrounding the first color filter portion CF1. The first color filter portion CF1 and the first viewing angle control portion CP1 may each be provided in plurality. The first color filter portion CF1 may be arranged between adjacent first viewing angle control portions CP1. A plurality of first color filter portions CF1 and a plurality of first viewing angle control portions CP1 may be alternately arranged in the first direction DR1. The first color filter portion CF1 and the first viewing angle control portion CP1 may be in contact with each other. The thickness of the first viewing angle control portion CP1 may be greater than the thickness of the first color filter portion CF1.

The first viewing angle control portion CP1 may include a first lower viewing angle control portion CP1a and a first upper viewing angle control portion CP1b on the top of the first lower viewing angle control portion CP1a.

The width of the first upper viewing angle control portion CP1b may be equal to the width of the first lower viewing angle control portion CP1a. The bottom surface of the first upper viewing angle control portion CP1b may be directly in contact with the top surface of the first lower viewing angle control portion CP1a. The thickness of the first lower viewing angle control portion CP1a may be equal to the thickness of the first color filter portion CF1. The first lower viewing angle control portion CP1a may be disposed on the same layer as the first color filter portion CF1. The first lower viewing angle control portion CP1a may include the same material as that of the first color filter portion CF1.

The first color filter portion CF1 may selectively transmit a first light (e.g., red light) and may block or absorb a second light (e.g., green light) and a third light (e.g., blue light). For example, the first color filter portion CF1 may be a red color filter and may include a red colorant. The first lower viewing angle control portion CP1a, like the first color filter portion CF1, may selectively transmit the first light (e.g., red light) and block or absorb the second light (e.g., green light) and the third light (e.g., blue light).

The first lower viewing angle control portion CP1a and the first upper viewing angle control portion CP1b may include colorants of different colors.

For example, the first upper viewing angle control portion CP1b may include the same material as that of the third color filter portion CF3 to be described later or the same material as that of the second color filter portion CF2 to be described later. Hereinafter, a description is made under the assumption that the first upper viewing angle control portion CP1b includes the same material as that of the third color filter portion CF3.

By including different color colorants in the first lower viewing angle control portion CP1a and the first upper viewing angle control portion CP1b, the first upper viewing angle control portion CP1b may control the viewing angle by absorbing or blocking the first light incident on the first upper viewing angle control portion CP1b from the first lower viewing angle control portion CP1a or the first color filter portion CF1. Accordingly, the user may see only the light emitted from the front by transmitting only the light passing through the first color filter portion CF1, e.g., a determined range of incident angles, and may not see the light emitted from the side passing through the first lower viewing angle pattern CP1a and the first upper viewing angle pattern CP1b. That is, the color filters may control light according to the user's viewing angle.

The second color filter CM2 may include a second color filter portion CF2 and a second viewing angle control portion CP2 surrounding the second color filter portion CF2. The second color filter portion CF2 and the second viewing angle control portion CP2 may each be provided in plurality. The second color filter portion CF2 may be arranged between adjacent second viewing angle control portions CP2. A plurality of second color filter portions CF2 and a plurality of second viewing angle control portions CP2 may be alternately arranged in the first direction DR1. The second color filter portion CF2 and the second viewing angle control portion CP2 may be in contact with each other. The thickness of the second viewing angle control portion CP2 may be greater than the thickness of the second color filter portion CF2.

The second viewing angle control portion CP2 may include a second lower viewing angle control portion CP2a and a second upper viewing angle control portion CP2b on top of the second lower viewing angle control portion CP2a.

The width of the second upper viewing angle control portion CP2b may be equal to the width of the second lower viewing angle control portion CP2a. The bottom surface of the second upper viewing angle control portion CP2b may be directly in contact with the top surface of the second lower viewing angle control portion CP2a. The thickness of the second lower viewing angle control portion CP2a may be equal to the thickness of the second color filter portion CF2. The second lower viewing angle control portion CP2a may be disposed on the same layer as the second color filter portion CF2. The second lower viewing angle control portion CP2a may include the same material as that of the second color filter portion CF2.

The second color filter portion CF2 may selectively transmit a second light (e.g., green light) and may block or absorb a first light (e.g., red light) and a third light (e.g., blue light). For example, the second color filter portion CF2 may be a green color filter and may include a green colorant. The second lower viewing angle control portion CP2a, like the second color filter portion CF2, may selectively transmit the second light (e.g., green light) and block or absorb the first light (e.g., red light) and the third light (e.g., blue light).

The second lower viewing angle control portion CP2a and the second upper viewing angle control portion CP2b may include colorants of different colors.

For example, the second upper viewing angle control portion CP2b may include the same material as that of the third color filter portion CF3 to be described later or the same material as that of the first color filter portion CF1. Hereinafter, a description is made on the basis of the second upper viewing angle control portion CP2b including the same material as that of the third color filter portion CF3.

By including different color colorants in the second lower viewing angle control portion CP2a and the second upper viewing angle control portion CP2b, the second upper viewing angle control portion CP2b may control the viewing angle by absorbing or blocking the second light incident on the second upper viewing angle control portion CP2b from the second lower viewing angle control portion CP2a or the second color filter portion CF2. Accordingly, the user may see only the light emitted from the front by transmitting only the light passing through the first color filter portion CF2, e.g., a determined range of incident angles, and cannot see the light emitted from the side passing through the first lower viewing angle pattern CP2a and the first upper viewing angle pattern CP2b. That is, the color filters may control light according to the user's viewing angle.

The third color filter CM3 may include a third color filter portion CF3 and a third viewing angle control portion CP3 surrounding the third color filter portion CF3. The third color filter portion CF3 and the third viewing angle control portion CP3 may each be provided in plurality. The third color filter portion CF3 may be arranged between adjacent third viewing angle control portions CP3. A plurality of third color filter portions CF3 and a plurality of third viewing angle control portions CP3 may be alternately arranged in the first direction DR1. The third color filter portion CF3 and the third viewing angle control portion CP3 may be in contact with each other. The thickness of the third lower viewing angle control portion CP3 may be equal to the thickness of the third color filter portion CF3.

The third viewing angle control portion CP3 may include a third lower viewing angle control portion CP3a and a third upper viewing angle control portion CP3b on the top of the third lower viewing angle control portion CP3a. The width of the third upper viewing angle control portion CP3b may be equal to the width of the third lower viewing angle control portion CP3a. The bottom surface of the third upper viewing angle control portion CP3b may be directly in contact with the top surface of the third lower viewing angle control portion CP3a. The thicknesses of the third lower viewing angle control portion CP3a and the third upper viewing angle control portion CP3b may each be less than the thickness of the third color filter portion CF3. The third lower viewing angle control portion CP3b may be disposed on the same layer as the third color filter portion CF3. The third lower viewing angle control portion CP3b may include the same material as that of the third color filter portion CF3.

The third color filter portion CF3 may selectively transmit a third light (e.g., blue light) and may block or absorb a first light (e.g., red light) and a second light (e.g., green light). For example, the third color filter portion CF3 may be a blue color filter and may include a blue colorant.

The third lower viewing angle control portion CP3a and the third upper viewing angle control portion CP3b may include colorants of different colors.

For example, the third upper viewing angle control portion CP3a may include the same material as that of the first color filter portion CF1 or the same material as that of the second color filter portion CF2. Hereinafter, a description is made under the assumption that the third upper viewing angle control portion CP3a includes the same material as that of the first color filter portion CF1.

By including different color colorants in the third lower viewing angle control portion CP3a and the third upper viewing angle control portion CP3b, the third upper viewing angle control portion CP3b may absorb or block the first light incident on the third upper viewing angle control portion CP3b from the third lower viewing angle control portion CP3a.

Accordingly, the user may see only the light emitted from the front by transmitting only the light passing through the third color filter portion CF3, e.g., with a determined range of incident angles, and cannot see the light emitted from the side passing through the third lower viewing angle pattern CP3a and the third upper viewing angle pattern CP3b. That is, the color filters may control light according to the user's viewing angle.

Meanwhile, according to an embodiment, the color filters CM1, CM2, and CM3 may be designed such that the corresponding color filter portions CF1, CF2, and CF3 may each be positioned further outward from the corresponding viewing angle control portion CP1, CP2, and CP3 in the corresponding pixels PX1, PX2, and PX3. That is, the first color filter portion CF1 may be positioned at the outermost edges of the first pixel PX1 in the second direction DR2, the second color filter portion CF2 may be positioned at the outermost edges of the second pixel PX2 in the second direction DR2, and the third color filter portion CF3 may be positioned at the outermost edges of the third pixel PX3 in the second direction DR2. As a result, it is possible to prevent the unintentional emission of the third light and the first light from each of the pixels PX1, PX2, and PX3 through the first upper viewing angle control portion CP1b, the second upper viewing angle control portion CP2b, and the third lower viewing angle control portion CP3a, respectively.

As shown in FIG. 3A, accordance to an embodiment, the viewing angle control portions CP1, CP2, and CP3 may be extended along the second direction DR2. That is, a plurality of first viewing angle control portions CP1 may be extended along the second direction DR2 and spaced apart from each other in the first direction DR1, a plurality of second viewing angle control portions CP2 may be extended along the second direction DR2 and spaced apart from each other in the first direction DR1, and a plurality of third viewing angle control portions CP3 may be extended along the second direction DR2 and spaced apart from each other in the first direction DR1. The viewing angle control portions CP1, CP2, and CP3 shown in FIG. 3A may serve to control the viewing angle in the first direction DR1.

Meanwhile, according to an alternative embodiment as shown in FIG. 3B, the viewing angle control portions CP1, CP2, and CP3 may be extended along the first direction DR1. That is, a plurality of first viewing angle control portions CP1 may be extended along the first direction DR1 and spaced apart from each other in the second direction DR2, a plurality of second viewing angle portions CP2 may be extended along the first direction DR1 and be spaced apart from each other in the second direction DR2, and a plurality of third viewing angle control portions CP3 parts may be extended along the first direction DR1 and spaced apart from each other in the second direction DR2. The viewing angle control portions CP1, CP2, and CP3 shown in FIG. 3A may control the viewing angle in the second direction DR2.

As shown in FIG. 4, the color filters CM1, CM2, and CM3 according to an embodiment may receive white light 1000. That is, the same light may be provided to color filters CM1, CM2, and CM3.

According to an embodiment, the viewing angle may be controlled by the viewing angle control portions CP1, CP2, and CP3 adjacently formed by stacking portions including colorants of different colors vertically adjacent the color filter portions CF1, CF2, and CF3. That is, the color filter portions CF1, CF2, and CF3 transmit light emitting frontward, and the lower viewing angle patterns CP1a, CP2a, and CP3a and the upper viewing angle patterns CP1b, CP2b, and CP3c stacked in the vertical direction block light emitting sideward, thereby controlling the light according to the user's viewing angle.

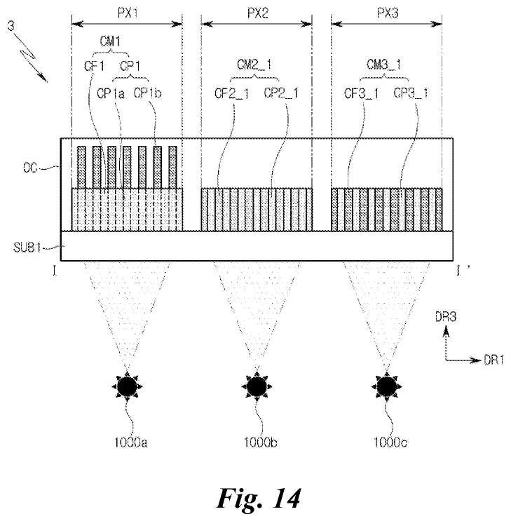

In some embodiments, different lights (refer to 1000a, 1000b, and 1000c in FIG. 14) may be provided to pixels PX1, PX2, and PX3.

In addition, by forming the viewing angle control portions CP1, CP2, and CP3 for controlling the viewing angle simultaneously during the process of forming the color filter portions CF1, CF2, and CF3 to emit light of specific colors for the corresponding pixels PX1, PX2, and PX3, it may be possible to simplify the manufacturing process and eliminate the need for a separate viewing angle control film to be adhered, resulting in reduced material costs and facilitating slim-down of the display device 1.

Hereinafter, a description is made of the method of manufacturing the display device 1 according to an embodiment.

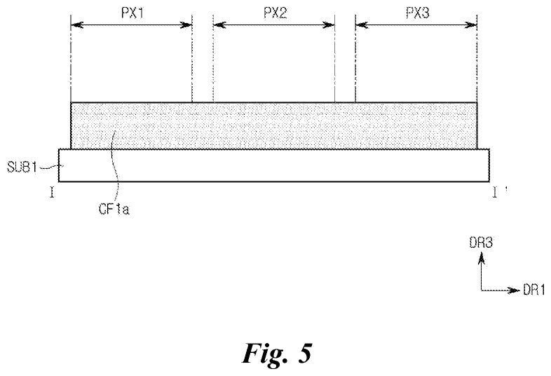

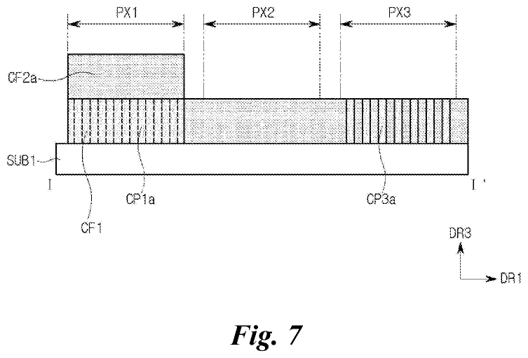

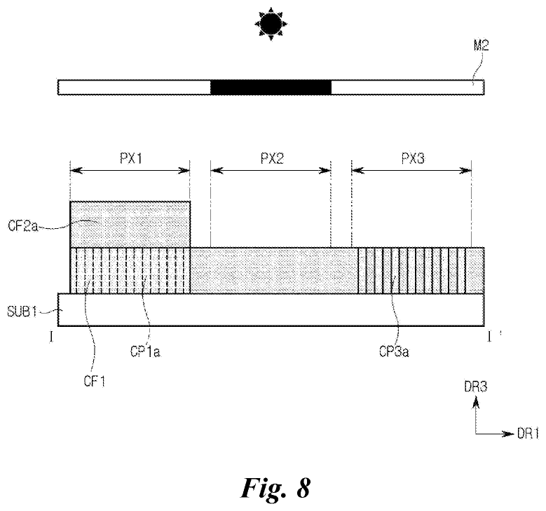

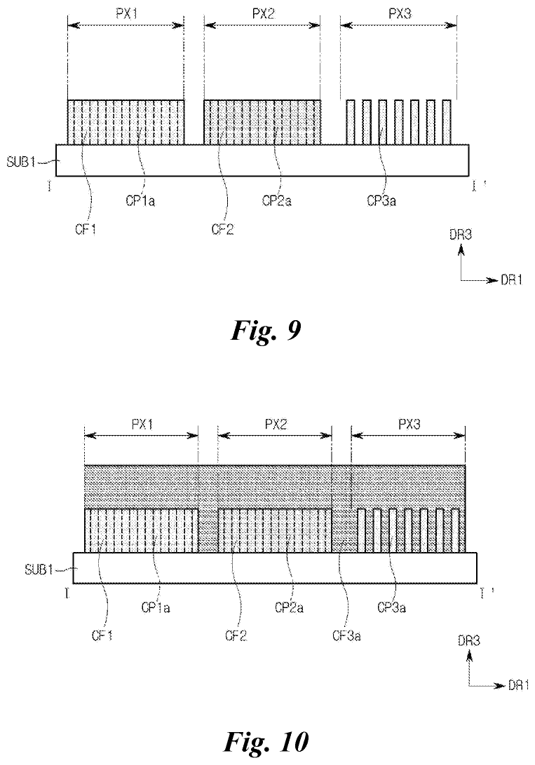

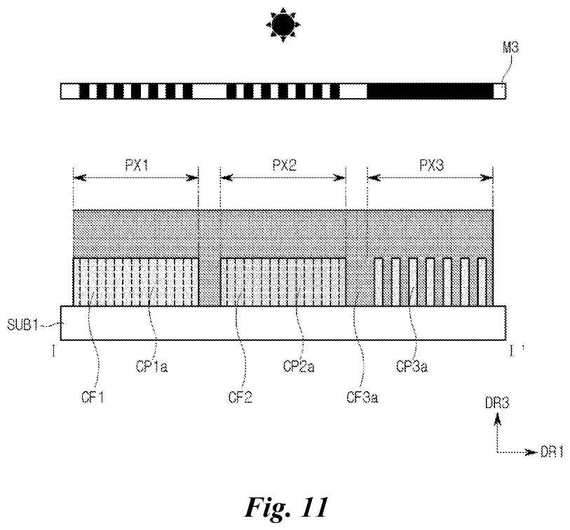

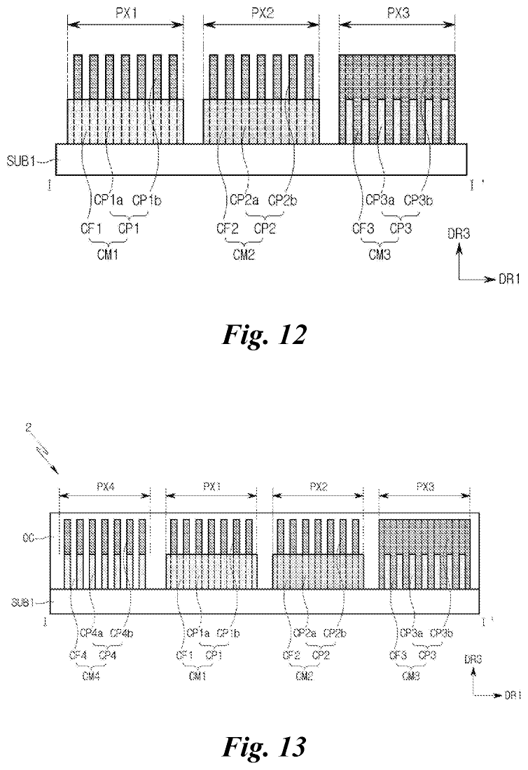

FIGS. 5 to 12 are cross-sectional views illustrating process steps of a method of manufacturing a display device according to an embodiment. The method for manufacturing a display device is described with reference to FIGS. 5 to 12, and FIGS. 1 and 2 may also be referenced if necessary.

First, as shown in FIGS. 2 and 5, a first color filter layer CF1a is formed on the first substrate SUB1. The first color filter layer CF1a may be arranged to cover the entire surface area across the pixels PX1, PX2, and PX3. The material of the first color filter layer CF1a may be the same as that of the first color filter portion CF1.

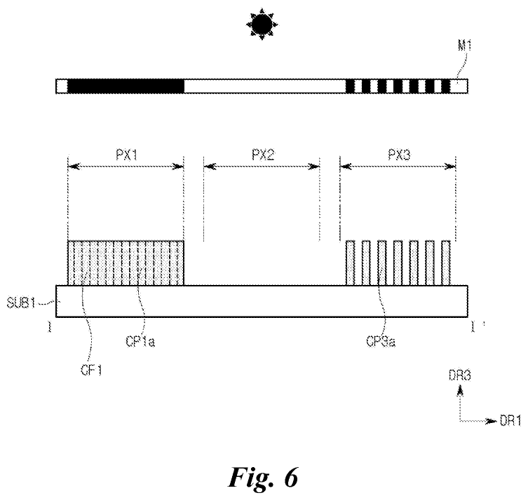

Next, as shown in FIGS. 2 and 6, the first color filter portion CF1 and the first lower viewing angle control portion CP1a of the first pixel PX1 and the third lower viewing angle control portion CP3a of the third pixel PX3 are formed on the first substrate using a first mask M1.

Next, with reference to FIGS. 2 and 7, a second color filter layer CF2a is formed to cover the entire surface area across the pixels PX1, PX2, and PX3. The material of the second color filter layer CF2a may be the same as that of the second color filter portion CF2. The second color filter layer CF2a may be arranged on the first color filter portion CF1 and the first lower viewing angle control portion CP1a of the first pixel PX1, on the entire area of the second pixel PX2, and between the adjacent third lower viewing angle control portions CP3a of the third pixel PX3.

Next, with reference to FIGS. 2, 8, and 9, using a second mask M2, the second color filter layer CF2a in the area except for the area of the second pixel PX2 is removed. The second color filter portion CF2 and the second lower viewing angle control portion CF2a may be formed in the second pixel PX2.

Next, with reference to FIGS. 2 and 10, the third color filter layer CF3a is formed over the entire area of the pixels PX1, PX2, and PX3. The material of the third color filter layer CF3a may be the same as that of the third color filter portion CF3. The third color filter layer CF3a may be arranged on the first color filter portion CF1 and the first lower viewing angle control portion CP1a in the first pixel PX1, on the second color filter portion CF2 and the second lower viewing angle control portion CF2a in the second pixel PX2, and on the third lower viewing angle control portion CP3a and between the adjacent third lower viewing angle control portions CP3a in the third pixel PX3.

Next, with reference to FIGS. 2, 11, and 12, using a third mask M3, the first upper viewing angle control portion CP1b of the first pixel PX1, the second upper viewing angle control portion CP2b of the second pixel PX2, and the third color filter portion CF3 and third upper viewing angle control portion CP3b of the third pixel PX3 are formed.

Hereinafter, a description is made of the display device 1 according to alternative embodiments.

FIG. 13 is a cross-sectional view of a display device according to another embodiment.

With reference to FIG. 13, the display device 2 according to this embodiment differs from the display device 1 of FIG. 2 in that it further includes a fourth pixel PX4. That is, the display area (DA in FIG. 1) further includes the fourth pixel PX4, which may be an area where the fourth light is emitted. The fourth light may be a white light.

The color filters may further include the fourth color filter CM4 in the fourth pixel PX4. The fourth color filter CM4 may include a fourth color filter portion CF4 and a fourth viewing angle control portion CP4 surrounding the fourth color filter portion CF4. The fourth color filter portion CF4 may include the same material as that of the overcoat layer OC. The fourth viewing angle control portion CP4 may include a fourth lower viewing angle control portion CP4a and a fourth upper viewing angle control portion CP4b on the top of the fourth lower viewing angle control portion CP4a. The bottom surface of the fourth upper viewing angle control portion CP4b may be directly in contact with the top surface of the fourth lower viewing angle control portion CP4a. The width of the fourth upper viewing angle control portion CP4b may be equal to the width of the fourth lower viewing angle control portion CP4a.

The fourth color filter portion CF4 may selectively transmit the fourth light (e.g., white light) and may block or absorb the first light (e.g., red light), the second light (e.g., green light), and a third light (e.g., blue light).

The fourth lower viewing angle control portion CP4a and the fourth upper viewing angle control portion CP4b may include colorants of different colors.

For example, the fourth upper viewing angle control portion CP4a may include the same material as that of the first color filter portion CF1 or the same material as that of the second color filter portion CF2. For example, the fourth upper viewing angle control portion CP4b may include the same material as that of the second color filter portion CF2 or the same material as that of the third color filter portion CF3.

By including different color colorants in the fourth lower viewing angle control portion CP4a and the fourth upper viewing angle control portion CP4b, the fourth upper viewing angle control portion CP4b may absorb or block the first light incident on the fourth upper viewing angle control portion CP4b from the fourth lower viewing angle control portion CP4a.

FIG. 14 is a cross-sectional view of a display device according to another embodiment.

With reference to FIG. 14, the display device 3 according to this embodiment differs from the display device 1 of FIG. 2 in that the second and third color filters CM2_1 and CM3_1 are different.

In more detail, the second color filter CM2_1 may include a second color filter portion CF2_1 and a second viewing angle control portion CP2_1 surrounding the second color filter portion CF2_1. The colorant of the second color filter portion CF2_1 may differ from that of the second viewing angle control portion CP2_1. The material of the second viewing angle control portion CP2_1 may be the same as that of the first color filter portion CF1 or the same as that of the third color filter portion CF3_1. Hereinafter, a description is made under the assumption that the material of the second upper viewing angle control portion CP2_1 is the same as that of the first color filter portion CF1. The thickness of the second color filter portion CF2_1 may be the same as that of the second viewing angle control portion CP2_1.

The third color filter CM3_1 may include a third color filter portion CF3_1 and a third viewing angle control portion CP3_1 surrounding the third color filter portion CF3_1. The colorant of the third color filter portion CF3_1 may differ from the colorant of the third viewing angle control portion CP3_1. The material of the third viewing angle control portion CP3_1 may be the same as that of the first color filter portion CF1 or the same as that of the second color filter portion CF2_1. Hereinafter, a description is made under the assumption that the material of the third viewing angle control portion CP3_1 is the same as that of the first color filter portion CF1. The thickness of the third color filter portion CF3_1 may be the same as that of the third viewing angle control portion CP3_1.

The first pixel PX1 may be provided with the first light 1000a on the first color filter CM1, the second pixel PX2 may be provided with the second light 1000b on the second color filter CM2_1, and the third pixel PX3 may be provided with the third light 1000c on the third color filter CM3_1. The first light 1000a may be a red light, the second light 1000b may be a green light, and the third light 1000c may be a blue light.

The second viewing angle control portion CP2_1 may block the second light 1000b to control the viewing angle, and the third viewing angle control portion CP3_1 may block the third light 1000c to control the viewing angle.

The additional description that has already been made with reference to FIG. 2 will be omitted.

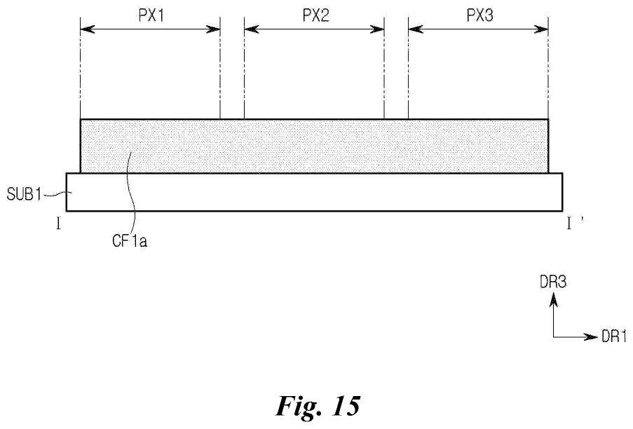

FIGS. 15 to 20 are cross-sectional views illustrating process steps of a method for manufacturing a display device according to another embodiment. The method for manufacturing a display device is described with reference to FIGS. 15 to 20, and FIG. 14 may also be referenced if necessary.

First, as shown in FIG. 15, a first color filter layer CF1a is formed on the first substrate SUB1. The first color filter layer CF1a may be arranged to cover the entire surface area across the pixels PX1, PX2, and PX3. The material of the first color filter layer CF1a may be the same as that of the first color filter portion CF1.

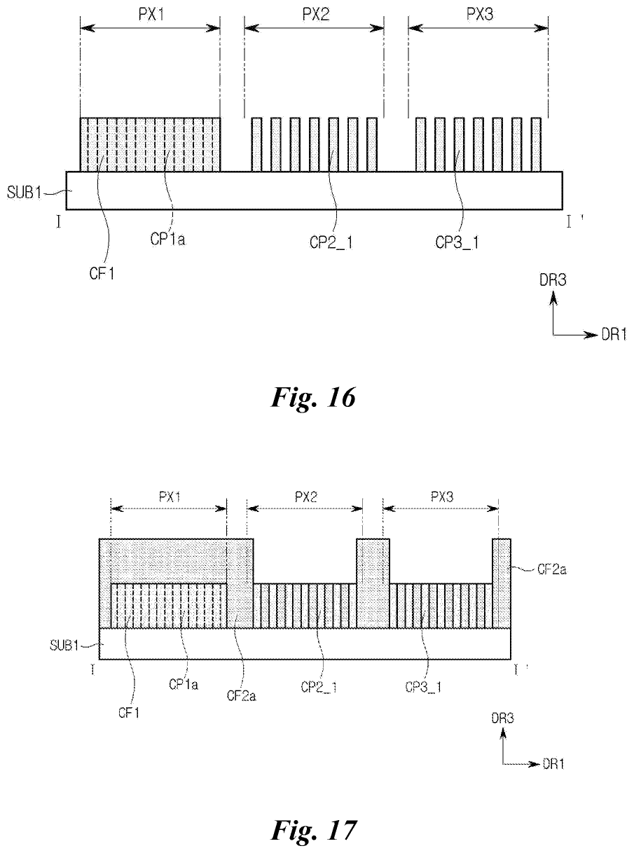

Next, as shown in FIGS. 14 and 16, the first color filter portion CF1 and the first lower viewing angle control portion CP1a of the first pixel PX1, the second viewing angle control portion CP2_1 of the second pixel PX2, and the third viewing angle control portion CP3_1 of the third pixel PX3 are formed.

Next, with reference to FIGS. 14 and 17, a second color filter layer CF2a is formed to cover the entire surface area across the pixels PX1, PX2, and PX3. The material of the second color filter layer CF2a may be the same as that of the second color filter portion CF2_1. The second color filter layer CF2a may be arranged on the first color filter portion CF1 and the first lower viewing angle control portion CP1a in the first pixel PX1, between the adjacent second viewing angle control portions CP2_1 in the second pixel PX2, and between the adjacent third lower viewing angle control portions CP3_1 in the third pixel PX3. The second color filter layer CF2a may be arranged between the pixels PX1, PX2, and PX3.

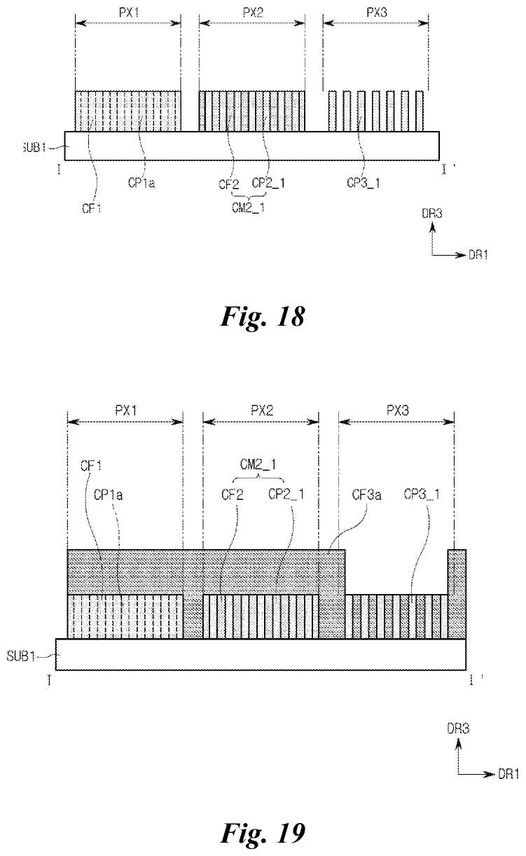

Next, with reference to FIGS. 14 and 18, the second color filter layer (CF2a in FIG. 17) is removed from the areas except for the area of the second pixel PX2. The second color filter portion CF2 and the second lower viewing angle control portion CF2_1 may be formed in the second pixel PX2.

Next, with reference to FIGS. 14 and 19, a third color filter layer CF3a is formed over the entire area across the pixels PX1, PX2, and PX3. The material of the third color filter layer CF3a may be the same as that of the third color filter portion CF3_1. The third color filter layer CF3a may be arranged on the first color filter portion CF1 and the first lower viewing angle control portion CP1a formed in the first pixel PX1, on the second color filter CM2_1 in the second pixel PX2, and between adjacent third lower viewing angle control portions CP3_1 in the third pixel PX3. The third color filter layer CF3a may be arranged between the pixels PX1, PX2, and PX3.

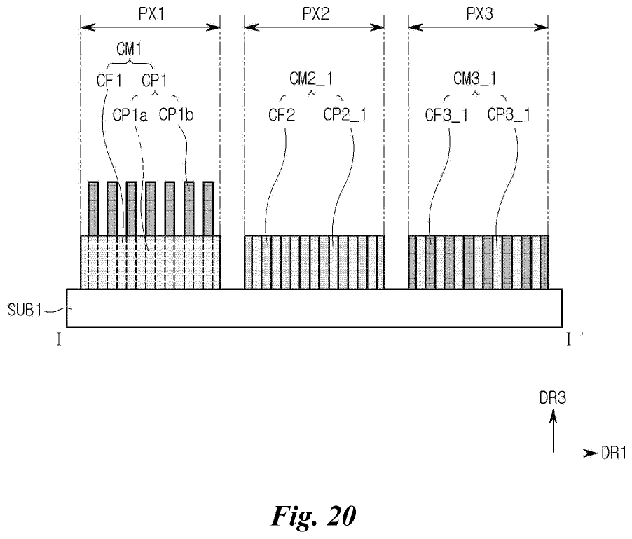

Sequentially, with reference to FIGS. 14 and 20, the first upper viewing angle control portion CP1b in the first pixel PX1 and the third color filter portion CF3_1 in the third pixel PX3 are formed.

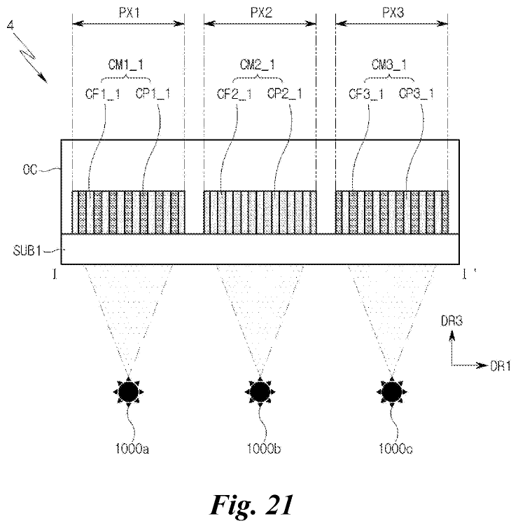

FIG. 21 is a cross-sectional view of a display device according to another embodiment.

With reference to FIG. 21, the display device 4 according to this embodiment differs from the display device 3 of FIG. 14 in that the first color filter CM1_1 includes the first color filter portion CF1_1 and the first viewing angle control portion CP1_1 surrounding the first color filter portion CF1_1.

In more detail, the first color filter CM1_1 may include the first color filter portion CF1_1 and the first viewing angle control portion CP1_1 surrounding the first color filter portion CF1_1. The colorant of the first color filter portion CF1_1 may differ from that of the first viewing angle control portion CP1_1. The material of the first viewing angle control portion CP1_1 may be the same as the material of the second color filter portion CF2_1 or the same as the material of the third color filter portion CF3_1. Hereinafter, a description is made under the assumption on the basis of the material of the first viewing angle control portion CP1_1 being the same as that of the third color filter portion CF3_1.

The thickness of the first color filter portion CF1_1 may be the same as that of the first viewing angle control portion CP1_1.

The first color filter CM1 of the first pixel PX1 may be provided with a first light 1000a. The first color filter CM1_1 may control the viewing angle by blocking the first light 1000a.

The additional description that has already been made with reference to FIG. 14 will be omitted.

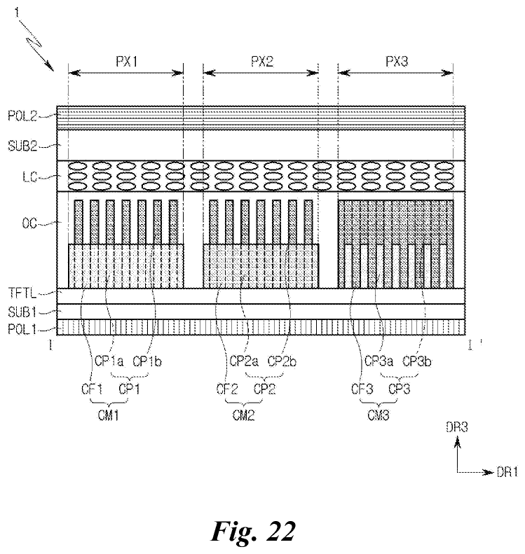

FIG. 22 is a detailed cross-sectional view of a display device according to another embodiment. FIG. 22 shows a detailed cross-sectional structure of the display device 1 described with reference to FIG. 2. The display device 1 shown in FIG. 22 may be a liquid crystal display device.

In more detail, the display device 1 according to an embodiment may include a first polarizing layer POL1 on the bottom surface of a first substrate SUB1, a thin film transistor layer TFTL on the top surface of the first substrate SUB1, color filters CM1, CM2, and CM3 on the TFTL, an overcoat layer OC on the color filters CM1, CM2, and CM3, a second substrate SUB2 on the overcoat layer OC, the second substrate SUB2 facing the first substrate SUB1, a second polarizing film POL on the top surface of the second substrate SUB2, and a liquid crystal layer LC between the second substrate SUB2 and the overcoat layer OC.

The polarizing layers POL1 and POL2, the thin film transistor layer TFTL, the liquid crystal layer LC, and the second substrate SUB2 are configurations widely known in the art and a detailed description thereof will be omitted.

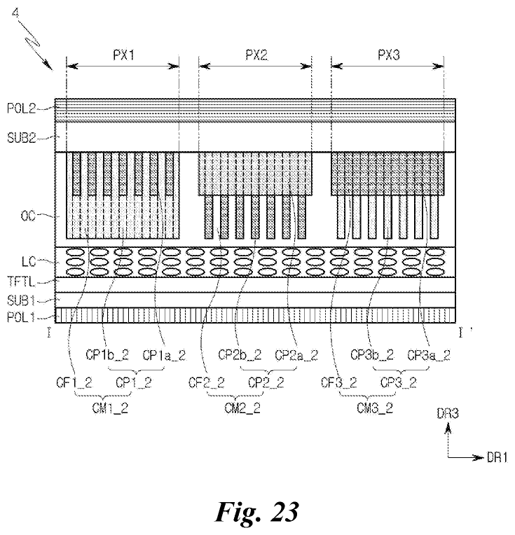

FIG. 23 is a cross-sectional view of a display device according to another embodiment.

With reference to FIG. 23, the display device 4 according to this embodiment differs from the display device 3 of FIG. 22 in that the color filters CM1_2, CM2_2, and CM3_2 and the overcoat layer OC are arranged between the liquid crystal layer LC and the second substrate SUB2.

The first color filter CM1_2 may include a first color filter portion CF1_2 and a first viewing angle control portion CP1_2 surrounding the first color filter portion CF1_2. The thickness of the first viewing angle control portion CP1_2 may be the same as the thickness of the first color filter portion CF1_2.

The first viewing angle control portion CP1_2 may include a first lower viewing angle control portion CP1a_2 and a first upper viewing angle control portion CP1b_2 on the top of the first lower viewing angle control portion CP1a_2.

The width of the first upper viewing angle control portion CP1b_2 may be equal to the width of the first lower viewing angle control portion CP1a_2. The bottom surface of the first upper viewing angle control portion CP1b_2 may be directly in contact with the top surface of the first lower viewing angle control portion CP1a_2. The thickness of the first lower viewing angle control portion CP1a_2 may be less than the thickness of the first color filter portion CF1_2.

The first upper viewing angle control portion CP1b_2 may include the same material as that of the first color filter portion CF1_2.

The first lower viewing angle control portion CP1a_2 and the first upper viewing angle control portion CP1b_2 may include colorants of different colors.

For example, the first lower viewing angle control portion CP1a_2 may include the same material as that of the third color filter portion CF3_2 or the same material as that of the second color filter portion CF2_2.

The second color filter CM2_2 may include a second color filter portion CF2_2 and a second viewing angle control portion CP2_2 surrounding the second color filter portion CF2_2. The thickness of the second viewing angle control portion CP2_2 may be greater than the thickness of the second color filter portion CF2_2.

The second viewing angle control portion CP2_2 may include a second lower viewing angle control portion CP2a_2 and a second upper viewing angle control portion CP2b_2 on the top of the second lower viewing angle control portion CP2a_2.

The width of the second upper viewing angle control portion CP2b_2 may be equal to the width of the second lower viewing angle control portion CP2a_2. The bottom surface of the second upper viewing angle control portion CP2b_2 may be directly in contact with the top surface of the second lower viewing angle control portion CP2a_2. The thickness of the second lower viewing angle control portion CP2a_2 may be equal to the thickness of the second color filter portion CF2_2. The second lower viewing angle control portion CP2a_2 may be disposed on the same layer as the second color filter portion CF2_2. The second lower viewing angle control portion CP2a_2 may include the same material as that of the second color filter portion CF2_2.

The second lower viewing angle control portion CP2a_2 and the second upper viewing angle control portion CP2b_2 may include colorants of different colors.

For example, the second upper viewing angle control portion CP2b_2 may include the same material as that of the third color filter portion CF3_2 or the same material as that of the first color filter portion CF1_2.

The third color filter CM3_2 may include a third color filter portion CF3_2 and a third viewing angle control portion CP3_2 surrounding the third color filter portion CF3_2. The thickness of the third viewing angle control portion CP3_2 may be greater than the thickness of the third color filter portion CF3_3.

The third viewing angle control portion CP3_2 may include a third lower viewing angle control portion CP3a_2 and a third upper viewing angle control portion CP3b_2 on the top of the third lower viewing angle control portion CP3a_2.

The width of the third upper viewing angle control portion CP3b_2 may be equal to the width of the third lower viewing angle control portion CP3a_2. The bottom surface of the third upper viewing angle control portion CP3b_2 may be directly in contact with the top surface of the third lower viewing angle control portion CP3a_2. The thickness of the third lower viewing angle control portion CP3a_2 may be equal to the thickness of the third color filter portion CF3_2. The third lower viewing angle control portion CP3a_2 may be disposed on the same layer as the third color filter portion CF3_2. The third lower viewing angle control portion CP3a_2 may include the same material as that of the third color filter portion CF3_2.

The third lower viewing angle control portion CP3a_2 and the third upper viewing angle control portion CP3b_2 may include colorants of different colors.

For example, the third upper viewing angle control portion CP3b_2 may include the same material as that of the first color filter portion CF1_2 or the second color filter portion CF2_2.

The additional description that has already been made with reference to FIGS. 2 and 22 will be omitted.

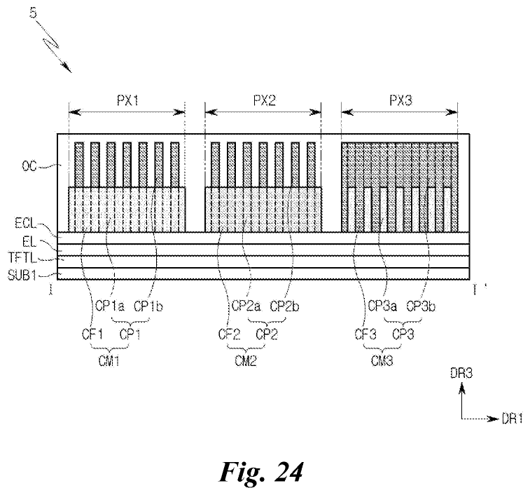

FIG. 24 is a cross-sectional view of a display device according to another embodiment.

With reference to FIG. 24, the display device 5 according to this embodiment differs from the display device 1 of FIG. 22 in that it is an organic light emitting display device.

In more detail, the display device 5 may include a first substrate SUB1, a thin film transistor layer TFTL on the first substrate SUB1, an organic light emitting layer EL on the thin film transistor layer TFTL, an encapsulation layer ECL on the organic light emitting layer EL, color filters CM1, CM2, and CM3 on the encapsulation layer ECL, and an overcoat layer OC on the color filters CM1, CM2, and CM3. The thin film transistor layer TFTL, the organic light emitting layer EL, and the encapsulation layer ECL are widely known in the art, and detailed descriptions thereof will be omitted below.

Although embodiments of this disclosure have been described above with reference to the accompanying drawings, it will be understood by those skilled in the art that this disclosure can be implemented without departing the technical concept of this disclosure. Therefore, it should be understood that the embodiments described above are examples and not limited in all respects.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first substrate comprising a display area comprising a plurality of pixels and a non-display area surrounding the display area; and
a color filter arranged on the first substrate,
wherein the color filter is configured to transmit a light incident from a front of the color filter and blocks other light.

2. The display device of claim 1, wherein the plurality of pixels comprises a first pixel emitting a first light, a second pixel emitting a second light, and a third pixel emitting a third light.

3. The display device of claim 2, wherein the color filter comprises a first color filter arranged in the first pixel, a second color filter arranged in the second pixel, and a third color filter arranged in the third pixel.

4. The display device of claim 3, wherein the first color filter comprises a first viewing angle control portion and a first color filter portion surrounding the first viewing angle control portion.

5. The display device of claim 4, wherein the first viewing angle control portion comprises a first lower viewing angle control portion and a first upper viewing angle control portion on top of the first lower viewing angle control portion.

6. The display device of claim 5, wherein the first lower viewing angle control portion is disposed on a same layer as the first color filter portion and includes a same material as the first color filter portion.

7. The display device of claim 5, wherein the first viewing angle control portion is provided in plurality, and the first color filter portion is disposed between adjacent first viewing angle control portions.

8. The display device of claim 5, wherein the first color filter portion is configured to transmit the first light and block the second light and the third light.

9. The display device of claim 5, wherein the second color filter comprises a second viewing angle control portion and a second color filter portion surrounding the second viewing angle control portion, the second viewing angle control portion comprises a second lower viewing angle control portion and a second upper viewing angle control portion on top of the second lower viewing angle control portion, and the second color filter portion transmits the second light and blocks the first light and the third light.

10. The display device of claim 9, wherein the third color filter comprises a third viewing angle control portion and a third color filter portion surrounding the third viewing angle control portion, the third viewing angle control portion comprising a third lower viewing angle control portion and a third upper viewing angle control portion on top of the third lower viewing angle control portion, the third color filter portion transmitting the third light and blocking the first light and the second light.

11. The display device of claim 10, wherein the first color filter, the second color filter, and the third color filter are each provided with a white light.

12. The display device of claim 10, wherein the plurality of pixels comprises a fourth pixel emitting a fourth light, the fourth light being a white light.

13. The display device of claim 12, wherein the color filter further comprises a fourth color filter arranged in the fourth pixel, the fourth color filter comprising a fourth viewing angel control portion and a fourth color filter portion surrounding the fourth viewing angle control portion.

14. The display device of claim 13, wherein the fourth viewing angle control portion comprises a fourth lower viewing angle control portion and a fourth upper viewing angle control portion on top of the fourth lower viewing angle control portion.

15. The display device of claim 14, wherein the first color filter is provided with the first light, the second color filter is provided with the second light, and the third color filter is provided with the third light.

16. A display device comprising:
a first substrate comprising a display area comprising a plurality of pixels and a non-display area surrounding the display area;
a thin film transistor layer on the first substrate;
a color filter on the thin film transistor layer;
a liquid crystal layer on the color filter; and
a second substrate on the liquid crystal layer,
wherein the color filter is structured to transmit a light incident with a first range of angles and blocks other light.

17. The display device of claim 16, wherein the plurality of pixels comprise a first pixel, a second pixel, and a third pixel, the color filter comprises a first color filter arranged in the first pixel, a second color filter arranged in the second pixel, and a third color filter arranged in the third pixel, and the liquid crystal layer is disposed between the color filter and the second substrate.

18. The display device of claim 17, wherein the color filter is disposed between the liquid crystal layer and the second substrate.

19. A display device comprising:
a first substrate comprising a display area comprising a plurality of pixels and a non-display area surrounding the display area;
a thin film transistor layer on the first substrate;
a light emitting layer on the thin film transistor layer;
a thin film encapsulation layer on the light emitting layer; and
a color filter on the thin film encapsulation layer,
wherein the color filter is structured to transmit a light incident thereon with an incident angle within a first range of angles and blocks other light.

20. The display device of claim 19, wherein the plurality of pixels comprise a first pixel, a second pixel, and a third pixel, the color filter comprises a first color filter arranged in the first pixel, a second color filter arranged in the second pixel, and a third color filter arranged in the third filter.
